(19) United States
(12) Patent Application Publication
(10) Pub. No.: US 2009/0042342 A1
(43) Pub. Date: Feb. 12, 2009

(54) METHOD FOR CRYSTALLIZATION OF AMORPHOUS SILICON BY JOULE HEATING

(75) Inventors: Jae-Sang Ro, Seoul (KR); Won-Eui Hong, Seoul (KR)

Correspondence Address: CANTOR COLBURN, LLP, 20 Church Street, 22nd Floor, Hartford, CT, 06103, US

(73) Assignee: ENSILTECH CO., LTD., Seoul (KR)

(21) Appl. No.: 12/281,418

(22) PCT Filed: Mar. 5, 2007
(86) PCT No.: PCT/KR2007/001083

§ 371 Date: Sep. 2, 2008

(30) Foreign Application Priority Data
Mar. 3, 2006 (KR) 10-2006-0020246

(51) Int. Cl. H01L 21/326; H01L 21/336

(52) U.S. Cl. 438/158; 438/466; 257/E21.414; 257/E21.327

(57) ABSTRACT

The present invention provides a method for preparation of crystallization of amorphous silicon thin film, which comprises providing a forming a amorphous silicon on a dielectric film formed on a transparent substrate; then forming a conductive layer on the top surface of substrate; applying an electric field to the conductive layer so as to generate heat; and crystallization of amorphous silicon thin film by the generated heat.

### FIELD OF THE INVENTION

The present invention relates to a method for crystallization of silicon thin film by Joule heating.

### BACKGROUND OF THE INVENTION

In the case of an active matrix organic light-emitting diode which has recently come into the spotlight for its applicability to the next-generation flat panel displays, the device operates in current-driven mode, whereas TFT-LCD operates in voltage-driven mode. Thus, LTPS-TFT is more required than a-Si TFT and the uniformity of grain size is a critical factor in large-size substrates.

In reality, the flat panel display industry faces limitations when using a low temperature crystallization method involving ELC or SLS which makes use of laser. In consideration of such facts, expectations of a new technology for producing polycrystalline silicon thin film having high quality by means of low temperature crystallization in a non-laser mode are very high.

Examples of the method of forming polycrystalline silicon at a low temperature by a non-laser mode include Solid Phase Crystallization (SPC), Metal Induced Crystallization (MIC), Metal Induced Lateral Crystallization (MILC), Applying an electric field Crystallization and the like.

The SPC method is advantageous in obtaining a homogeneous crystal structure using inexpensive equipments. However, since a high crystallization temperature and a long processing time are required, the method is disadvantageous in that a substrate having relatively low heat deflection temperature, such as glass substrate, cannot be used, and productivity is low. According to the SPC method, crystallization is achieved only when amorphous silicon thin film is subjected to annealing typically at a temperature of 600 to 700° C. for about 1 to 24 hours. Furthermore, in the case of polycrystalline silicon prepared by the SPC method, twin-growth is observed upon solid-state phase transition from the amorphous phase to the crystalline phase, and therefore crystal grains have a large amount of crystal lattice defects. These factors cause reduction in the mobility of electrons and holes in the produced polycrystalline silicon TFT and an increase in the threshold voltage.

The MIC method has an advantage in which contact between amorphous silicon and a specific metal allows crystallization of the amorphous silicon at a temperature far lower than the crystallization temperature of the SPC method. Examples of the metal that enables use of the MIC method include Ni, Pd, Ti, Al, Ag, Au, Co, Cu, Fe, Mn and the like. These metals react with amorphous silicon to form an eutectic phase or a silicide phase, thereby promoting low temperature crystallization. However, when the MIC method is applied to the actual process of polycrystalline silicon TFT manufacture, there is a high possibility of metal contamination in the channel.

The MILC method is an adaptation of the MIC method, which includes, instead of depositing metal on a channel, forming a gate electrode thereon, then depositing a thin metal layer on the source and drain in the self-aligned structure to prompt metal-induced crystallization, and subsequently inducing lateral crystallization toward the channel. The metals most frequently used in the MILC method are Ni and Pd. Although the polycrystalline silicon produced by MILC exhibits excellent crystal property and high field effect mobility compared with that produced by the SPC method, the former is reported to show a high leakage current characteristic. Thus, even though the MILC method reduces the problem of metal contamination as compared with the MIC method, the problem has not been completely solved yet. On the other hand, another available method is Field Aided Lateral Crystallization (FALC), as an improvement of MILC. The FALC method shows a higher crystallization rate compared with the MILC method and exhibits anisotropy in the direction of crystallization, yet this method does not provide a perfect solution for the metal contamination problem.

The crystallization methods such as MIC, MILC and FALC are effective in that the crystallization temperature is lowered, as compared with the SPC method; however, their common drawback is that crystallization is induced by metal. Accordingly, this means they are not free from the metal contamination problem.

Accordingly, the demand for a method of crystallization of amorphous silicon thin film has increased, exhibited such that the substrate disposed underneath is not damaged, and grains having high quality with virtually no defects; restrictions in the process operation, are overcome.

### SUMMARY OF THE INVENTION

The present invention has been made to solve the above problems, and other technical problems that have yet to be resolved.

Specifically, it is an object of the present invention to provide a method for crystallization of silicon thin film that is by means of low temperature crystallization in a non-laser mode, a strong electric field is applied to the conductive layer so as to heat the temperature of thin film to high temperature within a very short time without transforming the substrate, in turn enabling crystallization, elimination of lattice defects, crystal growth, dopant activation and the like.

In order to achieve the above objects, the method for preparation of polycrystalline silicon thin film suggested in the invention includes the steps of forming an active layer of amorphous silicon state on a dielectric film disposed on a transparent substrate; forming a conductive layer on the top surface of thus prepared substrate; and applying an electric field to the conductive layer to crystallize the amorphous silicon thin film by means of the heat generated from the conductive layer.

The electric field application to the conductive layer is performed by applying energy with a power density that can generate sufficiently intense heat to induce crystallization of amorphous silicon thin film by Joule heating. The application power density may be 100 W/cm²˜1,000,000 W/cm², and preferably 1000 W/cm²-100,000 W/cm². The electric current to be applied may be a direct current or an alternating current. The duration of the field application may be 1/10,000,000 to 1 sec as the time taken for continuous application, and preferably 1/100,000 to 1/10 sec. Such application of an electric field can be repeated a number of times on a regular basis or an irregular basis.

According to the invention, the intense heat is generated within a relatively short time by applying an electric field to the conductive layer, and this heat is transferred to the silicon thin film mainly by conduction and allows implementation of crystallization of amorphous silicon, elimination of crystal defects, dopant activation, and the like.

Meanwhile, since the silicon thin film compared with the transparent substrate is relatively very thin, the heat conduction from a conductive layer heated to high temperature within a very short time makes elevate the temperature of silicon thin film. However, it does not elevate the temperature of relatively thick substrate to high temperature because the total conduction energy is small in view of the thickness of substrate. Therefore, the substrate disposed underneath does not undergo thermal deformation even though an intense heat to enable heat treatment of the silicon thin film is generated.

In an embodiment, the method for crystallization of silicon thin film may comprise the steps of forming an active layer of amorphous silicon state and a source drain Si-layer doped with n³⁰ on a dielectric film disposed on a transparent substrate; forming a conductive layer on the top surface of thus prepared substrate; and applying an electric field to the conductive layer to crystallize the amorphous silicon thin film by means of the heat generated from the conductive layer.

The amorphous silicon and n³⁰ doped amorphous silicon thin film are preferably an active layer of amorphous silicon state and a n⁺-doped source drain Si-layer, respectively.

In such structure that the amorphous silicon thin film and n⁺ doped amorphous silicon thin film have been formed by a continuous deposition, when crystallization of amorphous silicon thin film is performed within a short time using the intense heat obtained by applying an electric field to the conductive layer, the crystallization can be accomplished while n⁺ dopant being almost not diffused because the heat treatment time for crystallization is very short. Thus, it is possible to forms a staggered structure TFT, which cannot be made by the conventional heat treatment methods of laser process or SPC process and like, instead of Co-planar structure requiring an ion injection process. Further, such crystallization method has an advantage in which the ion injection process and activation-heat treatment process can be omitted in application to a mass production of TFT, thereby reducing the process cost and improving an overall uniformity of TFT.

The method for crystallization of silicon thin film may also comprise the steps of forming an active layer of amorphous silicon state and a source drain Si-layer doped with n⁺ on a dielectric film disposed on a transparent substrate; forming an island by patterning the active layer and source drain layer and then etching; forming a conductive layer on the top surface of thus prepared substrate; and applying an electric field to the conductive layer to crystallize the amorphous silicon thin film by means of the heat generated from the conductive layer.

In a preferred embodiment of such crystallization method, in case where the amorphous silicon thin film and n⁺ doped amorphous silicon thin film are an active layer of amorphous silicon state and a n⁺-doped source drain Si-layer, the island can be formed by patterning the active layer and source drain layer and then etching, and the crystallization of silicon thin film can be accomplished by patterning the conductive layer to which the electric field is applied to a data line of source drain.

Another embodiment, the method for crystallization of silicon thin film may comprise the steps of forming an active layer of amorphous silicon state on a dielectric film disposed on a transparent substrate; forming a protect layer on the top surface of thus prepared substrate, except for a portion where electrodes will be formed at both ends of the substrate; forming a conductive layer on the top surface of thus prepared substrate; applying an electric field to the conductive layer to crystallize the amorphous silicon thin film by means of the heat generated from the conductive layer.

In addition, the method for crystallization of silicon thin film may comprise the steps of forming an active layer of amorphous silicon state on a dielectric film disposed on a transparent substrate; forming a gate electrode with a gate dielectric film being disposed on the active layer; forming source and drain regions doped with impurity at the predetermined portion of the active layer; forming a protect layer on the top surface of thus prepared substrate including the gate electrode, except for a portion where electrodes will be formed at both ends of the substrate; performing the photo-lithograph about the protect layer to expose the source and drain regions; forming a conductive layer on the top surface of thus prepared substrate; and applying an electric field to the conductive layer to anneal the active layer by means of the heat generated from the conductive layer.

In a preferred embodiment of the above method for crystallization, the heat treatment of an amorphous silicon (a-Si) thin film, an amorphous/polycrystalline silicon thin film, or a polycrystalline silicon (Poly-Si) thin film may be carried out in the annealing step of the active layer. Also, the doped silicon thin film in the source and drain regions are simultaneously subjected to the crystallization and dopant activation.

Meanwhile, the method for crystallization of silicon thin film may comprise the steps of forming a gate electrode on the substrate; forming a first dielectric film on the top surface of thus prepared substrate, except for a portion where electrodes will be formed at both ends of the gate electrode; deposing an amorphous silicon thin film and a doped amorphous silicon thin film successively on the first dielectric film; forming a conductive layer on the top surface of thus prepared substrate including the both ends of the gate electrode; and applying an electric field to the conductive layer to crystallize the amorphous silicon thin film and doped amorphous silicon thin film by means of the heat generated from the conductive layer.

The present invention also provides a method for crystallization of silicon thin film, comprising the steps of forming a conductive layer on a transparent substrate; forming a dielectric film on the conductive layer; forming an active layer of amorphous silicon state on the dielectric film disposed on the conductive layer; and applying an electric field to the conductive layer to crystallize the amorphous silicon thin film by means of the heat generated from the conductive layer.

Preferably, the method may comprise the steps of forming a conductive layer on a transparent substrate; forming a protect layer on the top surface of thus prepared substrate, except for a portion which will be connected to both ends of an active layer and a portion where electrodes will be formed; forming an active layer except for a portion where electrodes will be formed; and applying an electric field to the conductive layer to crystallize the amorphous silicon thin film by means of the heat generated from the conductive layer.

Meanwhile, in a preferred embodiment, the conductive layer and the active layer of amorphous silicon state may be electrically connected at both ends to which the electric field is applied. Thus, such structure can prevent generation of arc.

In an embodiment, the method for crystallization of silicon thin film may comprise the steps of forming a conductive layer on a transparent substrate; forming a dielectric film on the conductive layer; forming an active layer of amorphous silicon state and a source drain Si-layer doped with n⁺ on the dielectric film disposed on the conductive layer; and applying an electric field to the conductive layer to crystallize the amorphous silicon thin film by means of the heat generated from the conductive layer.

Preferably, the method may comprise the steps of forming a conductive layer on a transparent substrate; forming a protect layer except for a portion which will be connected to both ends of an active layer and a portion where electrodes will be formed; forming an active layer and n⁺ Si-layer except for a portion where electrodes will be formed; and applying an electric field to the conductive layer to crystallize the amorphous silicon thin film by means of the heat generated from the conductive layer.

Meanwhile, in a preferred embodiment, the conductive layer and the active layer of amorphous silicon state and the n⁺-doped source drain Si-layer are electrically connected at both ends to which the electric field is applied.

In the aforementioned structures where a conductive layer is formed on a transparent substrate, a dielectric layer may be disposed between the transparent substrate and conductive layer, so as to minimize heat conduction from the conductive layer to the transparent substrate and isolate effluence of impurities from the substrate.

The method for preparation of the invention and the polycrystalline silicon thin films obtained thereby have the following features or advantages compared with the conventional art.

Firstly, the process for implementing the method of crystallization is very simple and economic advantage thereof is high. The equipment for implementing the process of the invention is inexpensive, and techniques already established in the art can be used. The equipment required in carrying out the method of the invention is already established in the semiconductor and flat panel display industries, thus, the process of the invention can be carried out by directly applying the conventional techniques or through slight modification of the conventional techniques.

Secondly, the method of the invention is suitable for mass production of polycrystalline silicon thin films having uniformity and high quality. According to the invention, crystallization proceeds over the entire area of the array at a low temperature within a short time, and thus the method of the invention is advantageous in treating a substrate having a large area and can provide a polycrystalline silicon thin film having regularity of high quality.

Thirdly, the method of the invention may use the same process as the staggered structure of amorphous silicon TFT production process. When crystallization is carried out as shown in FIG. 3 by using the continuous deposition method of the Si and n⁺ Si which is a-Si TFT production process regarding the staggered structure, the poly-Si TFT of staggered structure can be made.

Fourthly, the method of the invention can simultaneously perform the crystallization process and dopant activation process, specifically can be carried out the heat treatment for activation of an ion-implanted dopant and heat treatment for crystallization in the vicinity of a source/drain electrode at the same time, after makes a Co-planner structure as shown in drawing of the invention.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic diagram illustrating the constitution of a specimen for preparation of polycrystalline silicon thin film according to one embodiment of the invention;

FIG. 2 is a schematic diagram illustrating the constitution of a specimen for preparation of polycrystalline silicon thin film according to one embodiment of the invention;

FIG. 3 is a schematic diagram illustrating the constitution of a specimen for preparation of polycrystalline silicon thin film according to one embodiment of the invention;

FIG. 4 is a schematic diagram illustrating the constitution of a specimen for preparation of polycrystalline silicon thin film according to one embodiment of the invention;

FIGS. 5 and 6 are schematic diagrams illustrating the constitution of specimens for preparation of polycrystalline silicon thin film according to another embodiment of the invention;

FIG. 7-(a) is a photograph showing a specimen of Example 1 having an amorphous silicon thin film before application of an electric field, at room temperature, 7-(b) is a photograph showing luminescence of the silicon thin film caused by high temperature heating due to Joule heating by application of an electric field in Example 1; 7-(c) is a photograph of a specimen with the silicon thin film converted to a polycrystalline silicon thin film after a single application of an electric field at room temperature in Example 1;

FIG. 8-(a) is a photograph showing a specimen of Example 2 having an amorphous silicon thin film before application of an electric field, at room temperature, 8-(b) is a photograph showing luminescence of the silicon thin film caused by high temperature heating due to Joule heating by application of an electric field in Example 2; 8-(c) is a photograph of the specimen with the silicon thin film converted converted to a polycrystalline silicon thin film after a single application of an electric field at room temperature in Example 2;

FIG. 9 is a photograph (magnification: ×200,000) showing the results of Bright Field TEM analysis of the polycrystalline silicon thin film of Example 2 after annealing;

FIG. 10 to 16 are schematic diagrams illustrating a manufacturing process according to one embodiment to form TFT by crystallizing an amorphous silicon thin film according to method of the invention.

### DETAILED DESCRIPTION OF PREFERRED EMBODIMENTS

Hereinafter, embodiments of the invention will be described in detail with reference to drawings, which are not, however, intended to limit the scope of the invention.

FIG. 1 shows a schematic diagram of the constitution of the substrate according to one embodiment of the invention for crystallization of amorphous silicon thin film.

Referring to FIG. 1, on substrate 20, a dielectric layer 40, an amorphous silicon (a-Si) thin film 30 and a second dielectric layer 42, a conductive layer 50 are successively formed, and an electric field is applied to the conductive layer 50.

The material for substrate 20 is not particularly limited, and transparent substrate materials such as, for example, glass, quartz and plastics can be used, while glass is more preferred in the economical aspect. However, according to the recent research trend in the field of flat panel display, researches are being conducted extensively on plastic-based substrates having excellent impact resistance and convenience of manufacturing process, and the method of the invention can be directly applied to such plastic-based substrates.

Meanwhile, the first dielectric layer 40 is used for the purpose of preventing effluence of substance contained in the substrate 20, which may possibly be generated in the subsequent processes, for example, an alkali substance in the case of a glass substrate. This layer is generally formed by depositing silicon oxide (SiO₂) or silicon nitride, and the thickness is preferably in the range of 2,000 to 5,000 Å, without being limited to this range. Depending on the progress of technology in the future, an amorphous silicon thin film 30 may be possibly formed directly on the substrate without the dielectric layer 40, and since the method of the invention is applicable to such structure, it is to be understood that the scope of the invention includes such structure.

The amorphous silicon thin film 30 can be formed by, for example, low pressure chemical vapor deposition, high pressure chemical vapor deposition, plasma enhanced chemical vapor deposition (PECVD), sputtering, vacuum evaporation or the like, but the PECVD method is preferably used. The thickness of the thin film is preferably in the range of 300 to 1000 Å, without being limited to this range. In addition, an amorphous silicon thin film 30 may be a Si single thin film, or a-Si and n⁺ Si double layer structure.

The second dielectric layer 42 takes the role of preventing contamination of the amorphous silicon thin film 30 by the conductive layer 50 during the annealing process, and the layer may be formed with the same material as that used for the first dielectric layer 40. Where n⁺ Si is sequently deposited on a-Si, the second dielectric layer may be omitted because there is not the contamination problem caused by conductive materials.

Conductive layer 50 is a thin layer of electrically conductive material and can be formed by, for example, sputtering, vacuum evaporation or the like. The conductive layer 50 needs to maintain a uniform thickness so as to have uniform heating during Joule heating process caused by the following field application. In the case of forming the second dielectric layer 42, a part of the periphery of conductive layer 50 is contacted with the silicon thin film 30, thereby preventing generation of arcs in the application of an electric field. The conductive layer 50 may possibly be, for example, an ITO thin film or other transparent conductive films, or a metallic thin film.

The application of an electric field to the conductive layer 50 may be implemented at room temperature, may be preliminarily heated to an appropriate temperature range. This appropriate temperature range means a temperature range where substrate 20 is not damaged throughout the process, and preferably corresponds to a range of temperature lower than the heat deflection temperature of the substrate 20. The method of preheating is not particularly limited, and for example, methods such as placing the array in a general heat treatment furnace and irradiating radiant heat of a lamp or the like, may be used.

Application of an electric field to the conductive layer 50 is carried out by applying energy with a power density that can generate sufficiently intense heat to induce crystallization of the amorphous silicon thin film 30 for short time as described above by Joule heating.

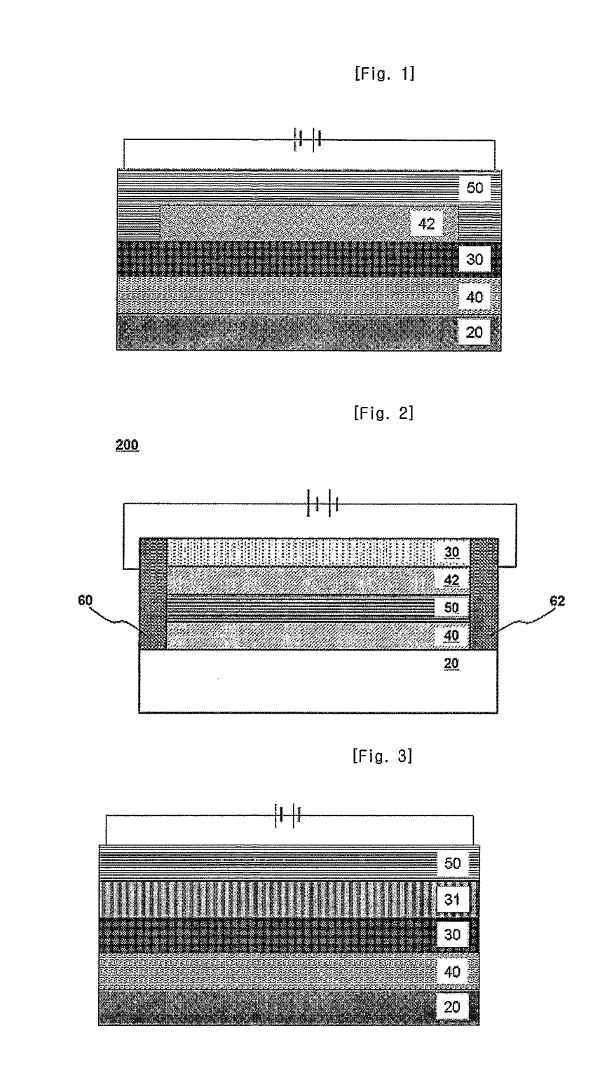

FIG. 2 shows a schematic diagram of the constitution of the substrate according to another embodiment of the invention for crystallization of amorphous silicon thin film.

Referring to FIG. 2, on substrate 20, a dielectric layer 40, a conductive layer 50, a second dielectric layer 42 and an amorphous silicon (a-Si) thin film 30 are successively formed, and an electric field is applied to the conductive layer 50. This structure is in principle identical to that of FIG. 1, except for the difference that it is impossible to exclude the second dielectric layer because a conductive material (conductive layer) is disposed below an active layer (amorphous silicon thin film).

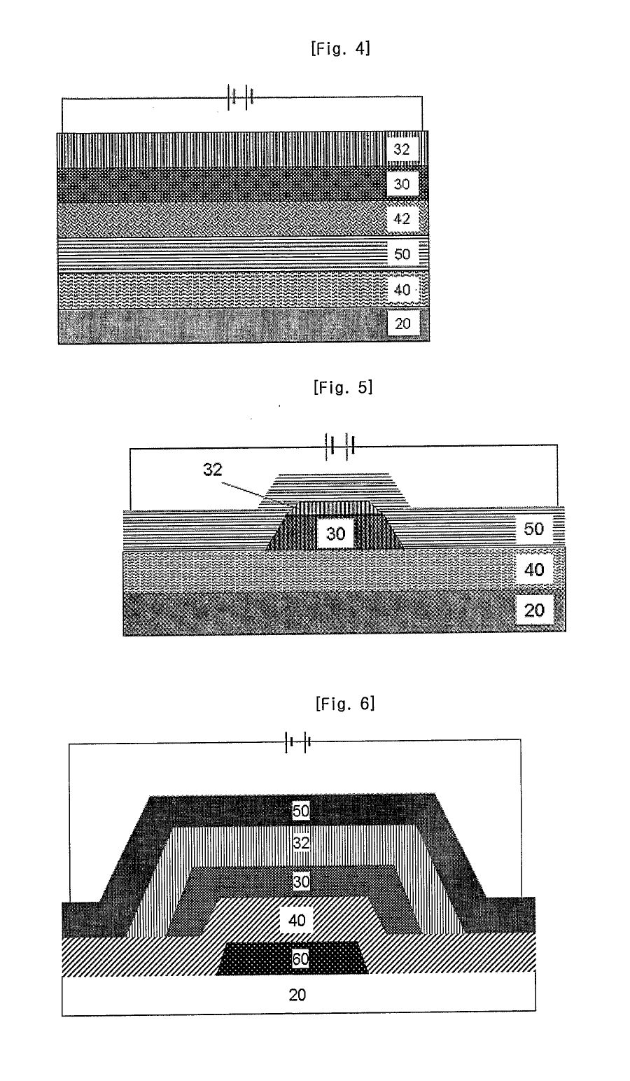

FIGS. 3 and 4 show schematic diagrams of the process according to another embodiments of the invention in which an active layer and n⁺ Si of source drain are successively deposited and then subjected to crystallization by application of an electric field during the deposition process of amorphous silicon thin film in the structure of FIGS. 1 and 2. The structure is possible to forming a staggered structure TFT.

Referring to FIG. 3, a dielectric layer 40 is formed on a substrate 20, and then n⁺ Si 31 which will form a source and drain is deposited on a-Si thin film 30 as an active layer by a continuous deposition, followed by application of an electric field. After application of an electric field, the a-Si thin film 30 and n⁺ a-Si thin film 31 are simultaneously subjected to crystallization.

Referring to FIG. 4, on substrate 20, a dielectric layer 40 and conductive layer 50 and dielectric layer 42 are subsequently formed, and n⁺ Si 32 which will form a source and drain is deposited on the a-Si thin film 30 as an active layer by a continuous deposition process, followed by application of an electric field to the conductive layer 50. After application of an electric field, the a-Si thin film 30 and n⁺ a-Si thin film 31 are simultaneously subjected to crystallization. For the convenience for expression, a power supply is illustrated to be connected to the top of a laminated structure in the drawing, but it is configured to be connected to only the conductive layer or the entire laminated structure including the active layer as in FIG. 2.

FIGS. 5 and 6 show schematic diagrams of the constitution of the substrates according to another embodiments of the invention.

First, referring to FIG. 5, on a substrate 20, a dielectric layer 40, an amorphous silicon (a-Si) thin film 30 and n⁺ source/drain layer 32 are successively formed, then an island is formed by a photo-lithography process about the amorphous silicon thin film and n⁺ doped amorphous silicon thin film, and then a conductive layer 50 is formed, followed by crystallization by application of an electric field. The conductive layer 50 as a source for joule heating can be later used as a data line of source/drain.

Referring to FIG. 6, on a substrate 20, a gate electrode 60, a dielectric layer 40, an amorphous silicon (a-Si) thin film 30, and a n⁺ source/drain layer 32 are successively formed, and an island are formed by a photo-lithography process about the amorphous silicon thin film and n⁺ doped amorphous silicon thin film, and then a conductive layer 50 are formed, followed by crystallization by application of an electric field. The conductive layer 50 which is joule heating source can be later used as a data line of source/drain.

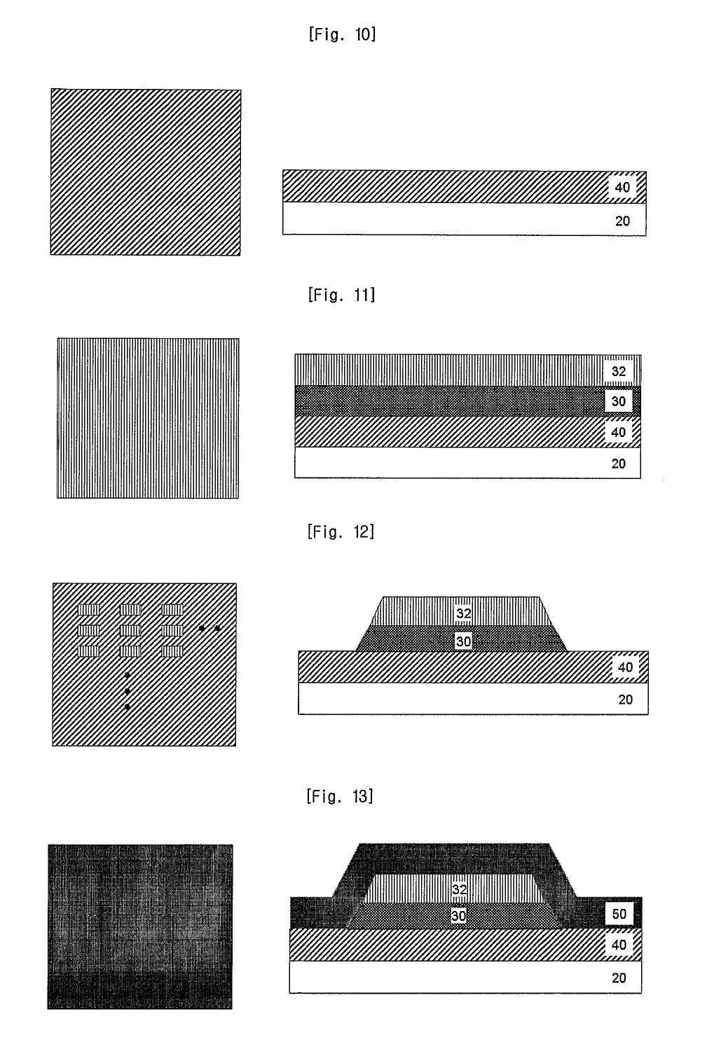

FIGS. 10 to 16 show schematic diagrams of the process in series for formation of TFT by crystallization an amorphous silicon thin film according to the method of the present invention.

First, referring to FIGS. 10 to 13, on substrate 20, a dielectric layer 40, an amorphous silicon (a-Si) thin film 30 and n⁺ source/drain layer 32 are successively formed, and an island is formed by a photo-lithography process about the amorphous silicon thin film and n⁺ doped amorphous silicon thin film, and then a conductive layer 50 is formed, followed by crystallization by application of an electric field to fabricate a substrate of the same structure (FIG. 13) as in FIG. 5 in which the conductive layer 50 can be later used as a data line of source/drain.

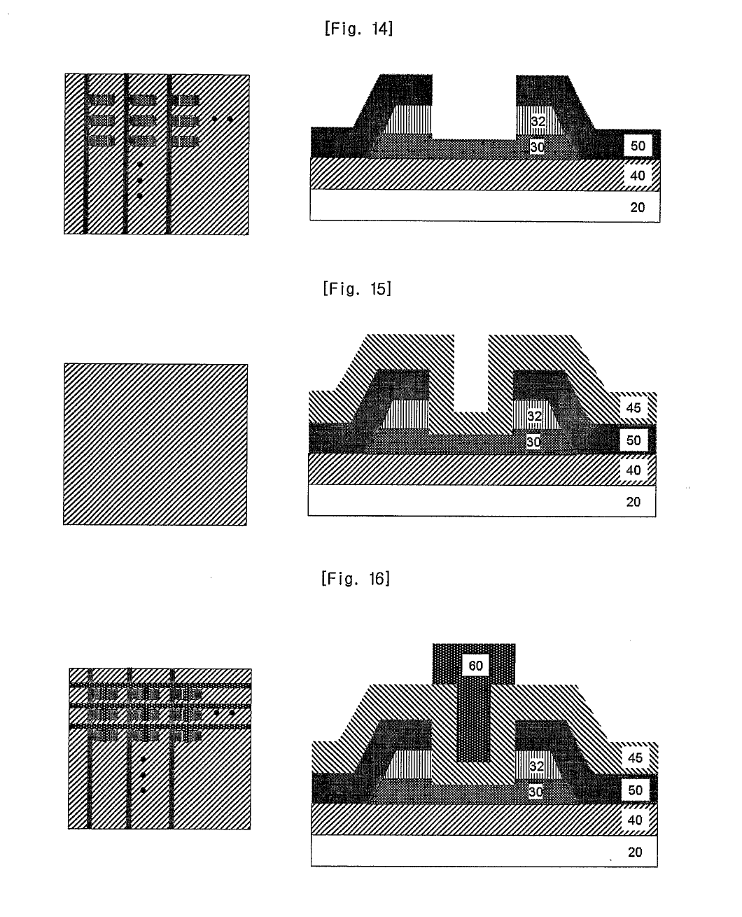

Referring to FIGS. 14 to 16, the conductive layer 50 according to FIG. 13 formed as a data line of source/drain is patterned to form a gate electrode, and a dielectric layer 45 is formed on the top surface of the conductive layer 50, and then a gate electrode 60 is formed on the patterned data line of source/drain, thereby making TFT. Through such series of preparation process, it is possible to fabricate TFT with a cost and effort much less than those of the conventional process.

The Joule heating as used in the method of the present invention, which takes place in the conductive layer by the field application, is defined as heating with a heat generated due to resistance of a conductive material upon flow of an electric current.

The amount of energy per unit time applied to the conductive layer by Joule heating due to field application can be expressed by the following formula:

W=V×I

In the above formula, W is defined as the amount of energy per unit time supplied by Joule heating, V as the voltage applied to both ends of the conductive layer, and I as the current.

It can be seen from the above formula that as the voltage (V) increases, and/or as the current (I) increases, the amount of energy per unit time applied to the conductive layer by Joule heating also increases. When the temperature of the conductive layer increases by Joule heating, there occurs heat conduction to the silicon thin film disposed above the conductive layer and the substrate (for example, glass substrate) disposed underneath the conductive layer. Thus, in order to elevate the temperature of the silicon thin film to a temperature which enables crystallization or dopant activation, by heat conduction without incurring thermal deformation of the glass substrate, an appropriate voltage and current are applied to the specimen for a short time in the method of the invention. In case the amount of applied energy is sufficient, the process can be completed with a single shot, while in case the amount is insufficient, the crystallization process can be accomplished with several shots at an appropriate time interval. FIG. 6 shows a graph of sequential repetitive shot process of one embodiment of method for application of an electric field.

When a joule heating for crystallization, important factor is the duration of the electric field application, and the duration of the field application (duration of a single application) in the method of the invention is preferably from 1/100,000 to 0.1 sec, as described above. Such a short time for crystallization allows crystallization or dopant activation to be achieved in the silicon thin film above without deformation of the substrate underneath (for example, glass substrate), in spite of the conductive layer being heated to a very high temperature. Also, it has an advantage that the conventional a-Si TFT process as it is can be used, because in the case of application to staggered structure, n⁺ dopant does not diffuse to an active layer.

### EXAMPLES

Hereinafter, the invention will be described in detail with reference to Examples, which are not intended to limit the scope of the invention by any means.

### Example 1

A SiO₂ layer (first dielectric layer) having a thickness of 3000 Å was formed on a glass substrate having a size of 2 cm in width×2 cm in length×0.7 mm in thickness, by PECVD method. An amorphous silicon thin film having a thickness of 500 Å was deposited on the first dielectric layer by PECD method, and then a SiO₂ layer (second dielectric layer) having a thickness of 1000 Å was deposited thereon by PECVD method again. An ITO thin film (conductive layer) having a thickness of 1000 Å was deposited on the second dielectric layer by sputtering. Thus, a substrate including an amorphous silicon thin film as shown in FIG. 1 was prepared. Resistance of the conductive layer was measured to be 20 Ω.

The process of applying an electric field of 300 V-15 A for 0.05 second at intervals of 1 minute to the conductive layer of thus prepared specimen was repeated five times in total at room temperature. As a result, the field application was carried out for approximately 0.25 second in total. The amount of energy applied to the conductive layer in such a single electric field application was 1125 Watt/cm².

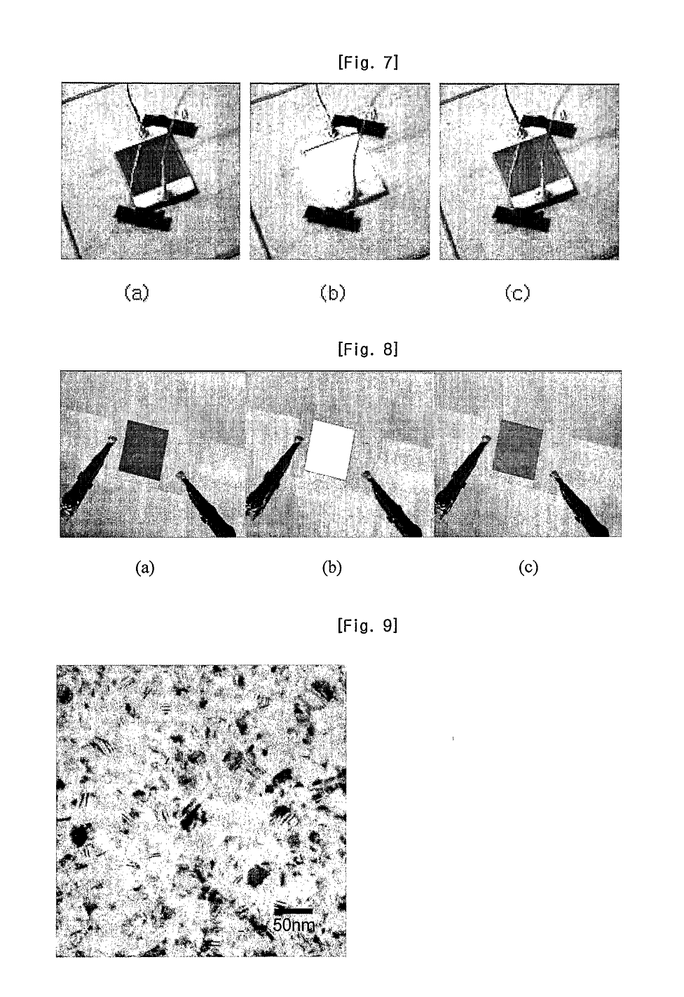

FIG. 7-(a) is a photograph of the specimen showing the amorphous silicon thin film at room temperature before electric field application, and 7-(b) is a photograph showing luminescence of the silicon thin film caused by high temperature heating due to Joule heating during electric field application, and 7-(c) is a photograph of the specimen having the silicon thin film converted to a polycrystalline silicon thin film after a single electric field application. From the luminescence phenomenon in 7-(b), it can be conjectured that an instantaneous temperature at the conductive layer is elevated to at least 1000° C. or above. Such intense heat is conducted to the silicon thin film disposed above and induces crystallization of the amorphous silicon.

### Example 2

A SiO₂ layer (first dielectric layer) having a thickness of 3000 Å was formed on a glass substrate having a size of 2 cm in width×2 cm in length×0.7 mm in thickness, by PECVD method. An ITO thin film (conductive layer) having a thickness of 1500 Å was deposited on the first dielectric layer by sputtering, and then a SiO₂ layer (second dielectric layer) having a thickness of 1000 Å was deposited thereon by PECVD method. After that, an amorphous silicon thin film having a thickness of 500 Å was deposited on the conductive layer by PECVD method. Thus, a substrate including an amorphous silicon thin film as shown in FIG. 2 was prepared. Resistance of the conductive layer was measured to be 10 Ω.

The process of applying constant current on 300 V-30 A to the conductive layer of thus prepared specimen for 0.009 second at a time interval of about 1 minute, was repeated ten times in total. The amount of energy per unit time applied to the conductive layer in the electric field application was 3000 Watt/cm².

FIG. 8-(a) is a photograph of the specimen showing the amorphous silicon thin film at room temperature before the electric field application, and 8-(b) is a photograph showing luminescence of the silicon thin film caused by high temperature heating due to Joule heating during the electric field application, and 8-(c) is a photograph of the specimen of converting to a polycrystalline silicon thin film after one electric field application. From the white luminescence phenomenon in 8-(b), it can be conjectured that an instantaneous temperature at the conductive layer is elevated to at least 1000° C. or above. Such intense heat is conducted to the silicon thin film which is disposed above and induces crystallization of the amorphous silicon.

FIG. 9 shows the results of a Bright Field TEM analysis of the silicon thin film after such heat treatment. Referring to FIG. 9, the microstructure of the polycrystalline silicon thin film prepared according to the present invention exhibits the structure of a nano-sized polycrystalline silicon thin film having crystal grains of uniform size. This structure is reported for the first time by the present invention, and such structure cannot be made by any conventional methods. In the case of the method according to the invention, the heating rate exceeds at least 1,000,000° C./sec, thus a microstructure formed at a high temperature is reflected intactly. On the other hand, even in the case of RTA with the highest heating rate among conventional heat treatment methods, the heat treatment rate is only about 100° C./sec. Therefore, the phase transition to polycrystalline silicon occurs in the course of heating, and the desired microstructure formed at a high temperature cannot be reflected. The polycrystalline silicon prepared in this Example has grains of very small size and shows grains of equiaxed morphology This structure is a microstructure which cannot be obtained in other heat treatment methods, the structure is expected to be very suitable for AMOLED applications. It was confirmed that in spite of such crystallization heat treatment, the glass substrate disposed underneath the conductive layer did not undergo deformation at all.

### Example 3

A SiO₂ layer (first dielectric layer) having a thickness of 3000 Å was formed on a glass substrate having a size of 2 cm in width×2 cm in length×0.7 mm in thickness, by PECVD method. An amorphous silicon thin film having a thickness of 800 Å was deposited on the first dielectric layer by PECVD method, and then a n⁺ Si layer (source drain layer) having a thickness of 300 Å was deposited thereon by PECVD method again. An ITO thin film (conductive layer) having a thickness of 1000 Å was deposited on the second dielectric layer by sputtering. Thus, a substrate including an amorphous silicon thin film as shown in FIG. 3 was prepared. Resistance of the conductive layer was measured to be 20 Ω.

The process of applying an electric field of 300 V-15 A to the conductive layer of thus prepared specimen for 0.05 second at a time interval of about 1 minute was repeated five times in total at room temperature. As a result, field application was carried out for approximately 0.25 second in total. The amount of energy applied to the conductive layer in such one electric field application was 1125 Watt/cm².

Despite the heat treatment for crystallization, it was found that dopants which exist in a source drain layer are not diffused to the silicon thin film which is crystallized, due to the fact that the heating time is very short. This result shows that it is possible to forms poly-TFT of a staggered structure which it is impossible to make by the conventional heat treatment technique.

### INDUSTRIAL APPLICABILITY

As described above, the crystallization method according to the present invention have effects that a polycrystalline silicon thin film which is completely free from the problem of contamination by catalyst metal appearing in polycrystalline silicon thin films produced by crystallization methods such as the MIC and MILC methods, and at the same time, is not accompanied by surface protrusions appearing in polycrystalline silicon thin films produced by the ELC method, while not causing thermal deformation of the glass substrate and markedly reducing the quantity of crystal lattice defects, the crystallization is carried out very uniformly, across the entire area of the thin film.

A person having ordinary skill in the art that pertains to the invention would be able to carry out various modifications and applications based on the description above, without departing from the scope and spirit of the invention as disclosed in the accompanying claims.

1. A method of crystallization of silicon thin film, comprising the steps:
forming an active layer of amorphous silicon state on a dielectric film disposed on a transparent substrate;
forming a conductive layer on the top surface of thus prepared substrate; and
applying an electric field to the conductive layer with a power density of 100 W/cm²˜1,000,000 W/cm² for 1/10,000,000˜1 sec to crystallize the amorphous silicon thin film by means of the heat generated from the conductive layer.

2. The method according to claim 1, which comprises the steps:
forming an active layer of amorphous silicon state and a source drain Si-layer doped with n⁺ on a dielectric film disposed on a transparent substrate;
forming a conductive layer on the top surface of thus prepared substrate; and
applying an electric field to the conductive layer to crystallize the amorphous silicon thin film by means of the heat generated from the conductive layer.

3. The method according to claim 1, which comprises the steps:
forming an active layer of amorphous silicon state and a source drain Si-layer doped with n⁺ on a dielectric film disposed on a transparent substrate;
forming an island by patterning the active layer and source drain layer and then etching;
forming a conductive layer on the top surface of thus prepared substrate; and
applying an electric field to the conductive layer to crystallize the amorphous silicon thin film by means of the heat generated from the conductive layer.

4. The method according to claim 3, which further comprises a step of patterning the conductive layer to which the electric field has been applied to a data line of source drain.

5. The method according to claim 1, which comprises the steps:
forming an active layer of amorphous silicon state on a dielectric film disposed on a transparent substrate;
forming a protect layer on the top surface of thus prepared substrate, except for a portion where electrodes will be formed at both ends of the substrate;
forming a conductive layer on the top surface of thus prepared substrate;
applying an electric field to the conductive layer to crystallize the amorphous silicon thin film by means of the heat generated from the conductive layer.

6. The method according to claim 5, which comprises the steps:
forming an active layer of amorphous silicon state on a dielectric film disposed on a transparent substrate;
forming a gate electrode with a gate dielectric film being disposed on the active layer;
forming source and drain regions doped with impurity at the predetermined portion of the active layer;
forming a protect layer on the top surface of thus prepared substrate including the gate electrode, except for a portion where electrodes will be formed at both ends of the substrate;
performing the photo-lithograph about the protect layer to expose the source and drain regions;
forming a conductive layer on the top surface of thus prepared substrate; and
applying an electric field to the conductive layer to anneal the active layer by means of the heat generated from the conductive layer.

7. The method according to claim 6, wherein the heat treatment of an amorphous silicon (a-Si) thin film, an amorphous/polycrystalline silicon thin film, or a polycrystalline silicon (Poly-Si) thin film is carried out by the annealing step.

8. The method according to claim 6, the doped silicon thin film in the source and drain regions is subjected to crystallization and dopant activation simultaneously.

9. The method according to claim 1, which comprises the steps:
forming a gate electrode on the substrate;
forming a first dielectric film on the top surface of thus prepared substrate, except for a portion where electrodes will be formed at both ends of the gate electrode;
deposing an amorphous silicon thin film and a doped amorphous silicon thin film successively on the first dielectric film;
forming a conductive layer on the top surface of thus prepared substrate including the both ends of the gate electrode;
applying an electric field to the conductive layer to crystallize the amorphous silicon thin film and doped amorphous silicon thin film by means of the heat generated from the conductive layer.

10. A method of crystallization of silicon thin film, comprising the steps:
forming a conductive layer on a transparent substrate;
forming a dielectric film on the conductive layer;
forming an active layer of amorphous silicon state on the dielectric film disposed on the conductive layer;
applying an electric field to the conductive layer with a power density of 100 W/cm²1,000,000 W/cm² for 1/10,000,000˜1 sec to crystallize the amorphous silicon thin film by means of the heat generated from the conductive layer.

11. The method according to claim 10, wherein the conductive layer and the active layer of amorphous silicon state are electrically connected at both ends to which the electric field is applied.

12. The method according to claim 10, which comprises the steps:
forming a conductive layer on a transparent substrate;
forming a dielectric film on the conductive layer;
forming an active layer of amorphous silicon state and source drain Si-layer doped with n on the dielectric film disposed on the conductive layer; and
applying an electric field to the conductive layer to crystallize the amorphous silicon thin film by means of the heat generated from the conductive layer.

13. The method according to claim 12, wherein the conductive layer and the active layer of amorphous silicon state and the n+-doped source drain Si-layer are electrically connected at both ends to which the electric field is applied.

14. The method according to claim 10, wherein a dielectric film is disposed between the transparent substrate and conductive layer.

15. The method according to claim 1, wherein the substrate is a glass substrate or a plastic substrate.

16. The method according to claim 1, wherein the conductive layer is an ITO thin film or a transparent conductive film of other types.

17. The method according to claim 1, wherein the conductive layer is a metallic thin film.

18. The method according to claim 1, wherein the dielectric layer is a silicon oxide layer or a silicon nitride layer.

19. The method according to claim 1, wherein the temperature in applying an electric field to the conductive layer is room temperature.

20. The method according to claim 1, which further comprises a step of preheating the array to a temperature range in which deformation of the substrate does not occur, before applying an electric field to the conductive layer.
